(19) United States
(12) Patent Application Publication
(10) Pub. No.: US 2026/0341314 A1
(43) Pub. Date: Oct. 29, 2026

(54) MEMORY DEVICE HAVING PASS TRANSISTOR

(71) Applicant: SK hynix Inc., Icheon-si (KR)

(72) Inventors: Jin Ho KIM, Icheon-si (KR); Chang Woo KANG, Icheon-si (KR); Jun Youp KIM, Icheon-si (KR); Byung Hyun JEON, Icheon-si (KR)

(21) Appl. No.: 19/326,101

(22) Filed: Sep. 11, 2025

(30) Foreign Application Priority Data
Apr. 28, 2025 (KR) 10-2025-0055091

(51) Int. Cl. G11C 5/06; G11C 5/02; H10B 41/27; H10B 41/40; H10B 43/27; H10B 43/40

(52) U.S. Cl. CPC G11C 5/063; G11C 5/025; H10B 41/27; H10B 41/40; H10B 43/27; H10B 43/40

(57) ABSTRACT

A disclosed memory device comprises: a memory cell array including a plurality of row lines extending in a first horizontal direction; a plurality of pass transistors connected to the plurality of row lines; and contacts connected to gate electrodes of the pass transistors. The plurality of pass transistors is arranged in a plurality of stages along a second horizontal direction perpendicular to the first horizontal direction. In each stage, two pass transistors are paired to share a gate electrode. A contact connected to a single gate electrode is disposed on an element isolation layer between the two paired pass transistors.

### CROSS-REFERENCES TO RELATED APPLICATION

The present application claims priority under 35 U.S.C. §119(a) to Korean patent application number 10-2025-0055091 filed on Apr. 28, 2025, which is incorporated herein by reference in its entirety.

### BACKGROUND

### 1. Technical Field

Embodiments of the present disclosure relate to a memory device having a pass transistor circuit.

### 2. Related Art

A memory device may be classified into a volatile memory device and a non-volatile memory device. Examples of non-volatile memory devices include flash memory devices, and resistive memory devices such as ReRAM (resistive random access memory), PRAM (phase change random access memory), and MRAM (magnetic random access memory). A memory device includes a memory cell array and a pass transistor circuit that delivers an operating voltage to word lines of the memory cell array.

### SUMMARY

Embodiments of the present disclosure provide a memory device having a pass transistor circuit.

According to embodiments of the present disclosure, a memory device may include: a memory cell array including a plurality of row lines extending in a first horizontal direction; a plurality of pass transistors connected to the plurality of row lines; and a plurality of contacts connected to gate electrodes of the plurality of pass transistors. The plurality of pass transistors may be arranged in a plurality of stages arranged in a second horizontal direction perpendicular to the first horizontal direction. In each stage, two pass transistors may be paired to share a gate electrode, and a contact connected to the shared gate electrode may be disposed in a vertical direction over an element isolation layer between the two paired pass transistors.

According to embodiments of the present disclosure, a memory device may include: a plurality of memory blocks arranged along a second horizontal direction perpendicular to a first horizontal direction, each including a plurality of electrode layers and a plurality of interlayer insulating layers alternately stacked in a vertical direction; a plurality of pass transistors connected to respective ones of the plurality of electrode layers; and a plurality of global row lines disposed on the plurality of pass transistors and connected to the electrode layers of the plurality of memory blocks through the plurality of pass transistors. The plurality of electrode layers in each of the plurality of memory blocks may include a plurality of odd electrode layers and a plurality of even electrode layers alternately stacked. The plurality of global row lines may include a plurality of odd global row lines and a plurality of even global row lines alternately arranged along the second horizontal direction. Each of the odd electrode layers of the plurality of memory blocks may be connected to one of the odd global row lines, and each of the even electrode layers of the plurality of memory blocks may be connected to one of the even global row lines.

According to embodiments of the present disclosure, a memory device may include: a first semiconductor layer; and a second semiconductor layer overlapping the first semiconductor layer in a vertical direction. The first semiconductor layer may include: a first substrate; and a plurality of memory blocks arranged on the first substrate along a second horizontal direction perpendicular to a first horizontal direction, each including a plurality of electrode layers and a plurality of interlayer insulating layers alternately stacked in the vertical direction. The second semiconductor layer may include: a second substrate; a plurality of pass transistors disposed on the second substrate and connected to the electrode layers of the plurality of memory blocks; and a plurality of contacts connected to gate electrodes of the plurality of pass transistors. The plurality of pass transistors may be arranged in a plurality of stages along the second horizontal direction. In each stage, two pass transistors may be paired to share a gate electrode, and a contact connected to the shared gate electrode may be disposed in the vertical direction over a device isolation region of the second substrate between the two paired pass transistors.

According to embodiments of the present disclosure, it is possible to provide a memory device having a pass transistor circuit.

### BRIEF DESCRIPTION OF THE DRAWINGS

FIG. 1 is a block diagram of a memory device according to an embodiment of the present disclosure.

FIG. 2 is a schematic diagram illustrating a memory device according to an embodiment of the present disclosure.

FIG. 3 illustrates first and second memory blocks, first and second pass transistor groups, a block selector, and a global row line decoder of FIG. 1.

FIG. 4 is a perspective view schematically illustrating first and second memory blocks of FIG. 1.

FIG. 5 is a plan view schematically illustrating a portion of a pass transistor circuit according to an embodiment of the present disclosure.

FIG. 6 is a cross-sectional view taken along line A–A′ of FIG. 5.

FIG. 7 is a cross-sectional view taken along line B–B′ of FIG. 5.

FIG. 8 is a cross-sectional view taken along line C–C′ of FIG. 5.

FIG. 9 is a plan view illustrating pass transistors and global row lines according to an embodiment of the present disclosure.

FIG. 10 is a cross-sectional view taken along line D–D′ of FIG. 9.

FIG. 11 is a cross-sectional view taken along line E–E″ of FIG. 9.

FIG. 12 is a cross-sectional view taken along line F–F″ of FIG. 9.

FIG. 13 is a plan view illustrating a pass transistor according to a comparative example.

FIG. 14 is a cross-sectional view taken along line G–G′ of FIG. 13.

FIG. 15 is a plan view illustrating a pass transistor according to another comparative example.

FIG. 16 is a cross-sectional view taken along line H–H′ of FIG. 15.

### DETAILED DESCRIPTION

Hereinafter, embodiments of the disclosure are described in detail with reference to the accompanying drawings. In assigning reference numerals to components in each drawing, identical components may be assigned the same reference numerals even when shown in different drawings. If details of known art or functions are deemed to obscure the subject matter of the disclosure, then such details may be omitted. As used herein, terms such as “includes,” “has,” or “is composed of” in relation to a component permits the inclusion of additional components unless terms like “only” are explicitly used. Additionally, unless the context clearly indicates otherwise, expressions in the singular, such as “a,” “an,” and “the” are intended to include their plural forms.

Such denotations as “first," "second," "A," "B," "(a)," and "(b)" may be used to describe components of the disclosure. These denotations are intended merely to distinguish one component from another, and are not intended to limit the nature, order, sequence, or number of the components.

Regarding the description of positional relationships between components, when two or more components are described as being "connected," "coupled," or "linked," it should be understood that they may be directly "connected," "coupled," or "linked," or may have an intervening component. Here, the intervening component may be included in one or more of the two or more components that are “connected,” “coupled,” or “linked” to each other.

When terms such as “after,” “next,” “subsequent to” or “before,” are used to describe the temporal or sequential relationships between components, operation methods, or fabrication methods, they may also encompass a non-continuous case unless terms like “immediately” or “directly” are explicitly used.

When a component is associated with a value or its corresponding information (e.g., level), such value or information may be interpreted to include tolerances arising due to various factors (e.g., process variations, internal or external impacts, or noise), even without explicit separate descriptions.

Hereinafter, various embodiments of the disclosure are described in detail with reference to the accompanying drawings.

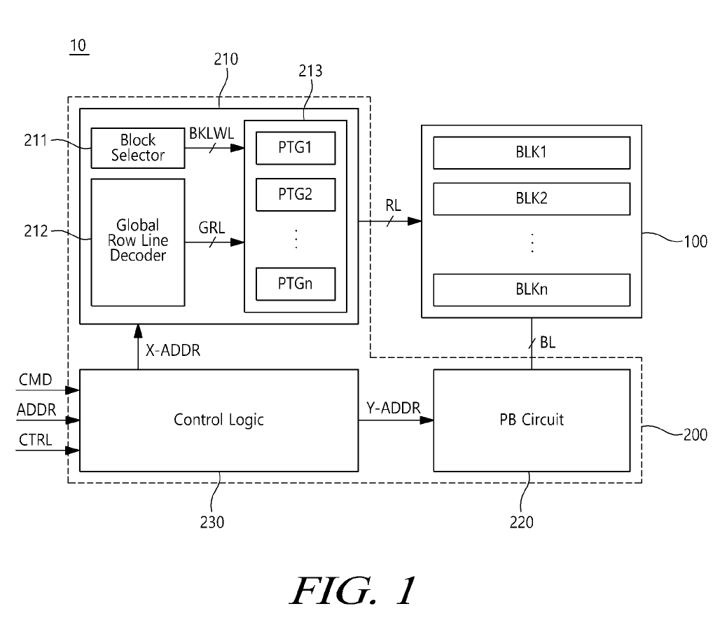

FIG. 1 is a block diagram of a memory device according to an embodiment of the present disclosure.

Referring to FIG. 1, a memory device 10 may include a memory cell array 100 and a peripheral circuitry 200. The peripheral circuitry 200 may include a row decoder 210, a page buffer circuit (PB Circuit) 220, and control logic 230. Although not shown, the peripheral circuitry 200 may further include a voltage generator, a data input/output circuit, a command decoder, and an address decoder.

The memory cell array 100 may include a plurality of memory blocks BLK1 to BLKn. Each of the memory blocks BLK1 to BLKn may include a plurality of memory cells. The memory cell may be, for example, a flash memory cell. The description below assumes that the memory cells are NAND flash memory cells; however, the present invention is not limited thereto. The memory cells may also be resistive memory cells, such as ReRAM, PRAM, or MRAM.

The memory cell array 100 may be connected to the row decoder 210 through row lines RL. The row lines RL may include at least one source select line, a plurality of word lines, and at least one drain select line. The memory cell array 100 may be connected to the page buffer circuit 220 through a plurality of bit lines BL.

The row decoder 210 may include a block selector 211, a global row line decoder 212, and a pass transistor circuit 213.

The block selector 211 may be connected to the pass transistor circuit 213 through block selection signal lines BLKWL. The block selector 211 may receive a row address X-ADDR from the control logic 230 and generate a block selection signal in response to the received row address X-ADDR.

The global row line decoder 212 may be connected to the pass transistor circuit 213 through global row lines GRL. The global row line decoder 212 may receive voltages from a voltage generator (not shown), and in response to control signals received from the control logic 230, may output the received voltages to the global row lines GRL.

The pass transistor circuit 213 may include a plurality of pass transistor groups PTG1 to PTGn, each corresponding to one of the plurality of memory blocks BLK1 to BLKn. Each of the pass transistor groups PTG1 to PTGn may be connected to a corresponding memory block through row lines RL. Each of the pass transistor groups PTG1 to PTGn may be connected to the global row line decoder 212 through the global row lines GRL. The global row lines GRL may be commonly connected to the plurality of pass transistor groups PTG1 to PTGn. The plurality of pass transistor groups PTG1 to PTGn may share the global row lines GRL.

In a first mode, the block selector 211 may provide a block selection signal to one selected pass transistor group among the pass transistor groups PTG1 to PTGn. In the first mode, the global row line decoder 212 may provide operating voltages to the pass transistor groups PTG1 to PTGn through the global row lines GRL. The pass transistor group that receives the block selection signal may deliver the operating voltages provided from the global row line decoder 212 to a corresponding memory block through the row lines RL. The first mode may be a normal operation mode. The normal operation may include a read operation, a write operation, an erase operation, or a read/write verify operation.

In a second mode, the block selector 211 may provide a block selection signal to at least one of the pass transistor groups PTG1 to PTGn. In the second mode, the global row line decoder 212 may provide test voltages to the pass transistor groups PTG1 to PTGn through the global row lines GRL. The pass transistor groups PTG1 to PTGn may deliver the test voltages provided from the global row line decoder 212 to the memory blocks BLK1 to BLKn through the row lines RL. The second mode may be a test operation mode.

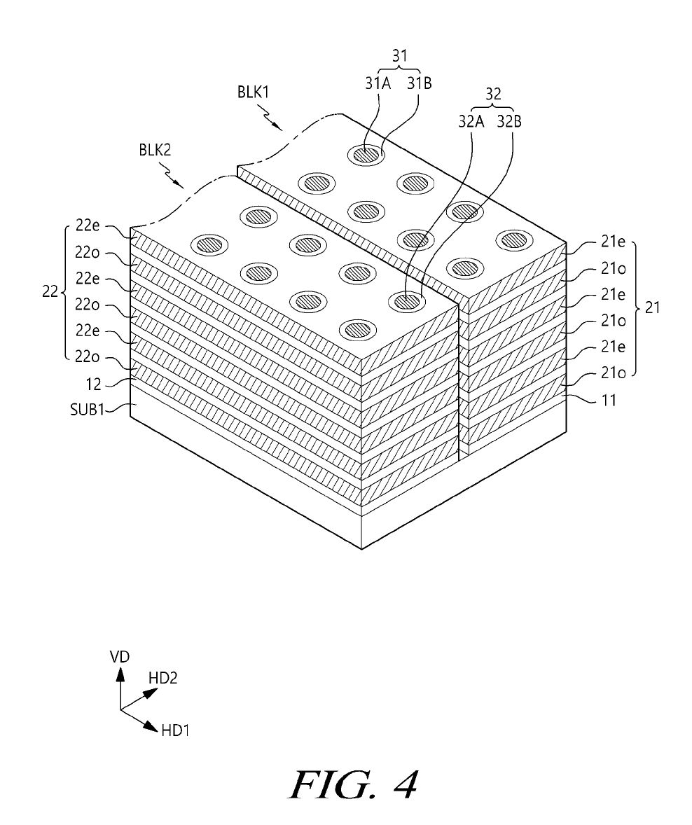

As will be described later with reference to FIG. 4, the row lines of each of the memory blocks BLK1 to BLKn may include alternately stacked odd row lines and even row lines. In the second mode, a first test voltage and a second test voltage may be alternately applied to the odd row lines. Likewise, the first test voltage and the second test voltage may be alternately applied to the even row lines. The first test voltage may be a high voltage, and the second test voltage may be a low voltage. The test voltage applied to the odd row lines may be different from the test voltage applied to the even row lines at the same time. While the first test voltage is applied to the odd row lines, the second test voltage may be applied to the even row lines, and while the second test voltage is applied to the odd row lines, the first test voltage may be applied to the even row lines. A stress may be applied to the memory cell array 100 due to a potential difference between the test voltages applied to the odd and even row lines. A defect such as a short circuit between adjacent row lines may occur at a weak point under such stress. After stress is intentionally applied in the second mode, a test may be performed to detect a growing bad block (GBB).

The page buffer circuit 220 may select a portion of the bit lines BL in response to a column address Y-ADDR. The page buffer circuit 220 may operate as a write driver or a sense amplifier depending on the operation mode.

The control logic 230 may control overall operations in the memory device 10. The control logic 230 may receive a command CMD, an address ADDR, and control signals CTRL, and based on the received command CMD, address ADDR, and control signals CTRL, may generate various control signals to program data into the memory cell array 100, to read data from the memory cell array 100, or to erase data stored in the memory cell array 100. The control logic 230 may output the row address X-ADDR and the column address Y-ADDR.

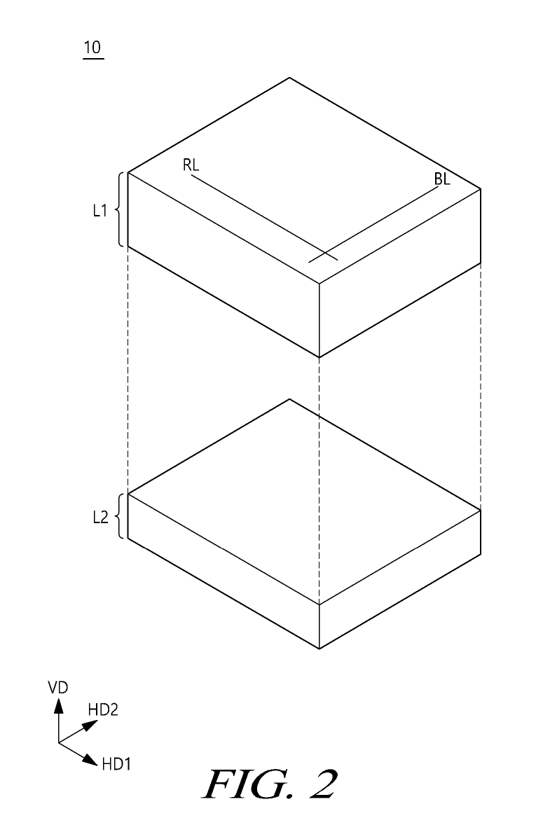

FIG. 2 is a schematic diagram illustrating a memory device according to an embodiment of the present disclosure.

Referring to FIG. 2, a memory device 10 may include a first semiconductor layer L1 and a second semiconductor layer L2. The first semiconductor layer L1 and the second semiconductor layer L2 may overlap in a vertical direction VD. Although the first semiconductor layer L1 and the second semiconductor layer L2 are shown spaced apart in the vertical direction VD in FIG. 2 for ease of understanding, it should be understood as having a structure in which the bottom surface of the first semiconductor layer L1 is in contact with the top surface of the second semiconductor layer L2.

In an embodiment, the peripheral circuitry (200 in FIG. 1) may be disposed in the second semiconductor layer L2, and the memory cell array (100 in FIG. 1) may be disposed in the first semiconductor layer L1.

In the first semiconductor layer L1, the plurality of row lines RL may extend in a first horizontal direction HD1, and the plurality of bit lines BL may extend in a second horizontal direction HD2. Although not illustrated, the first semiconductor layer L1 may include a first substrate. A stack may be formed on the first substrate by vertically stacking the plurality of row lines RL in the vertical direction VD. The row lines RL may be combined with cell plugs penetrating the stack in the vertical direction VD to form memory cells that are arranged three-dimensionally.

The second semiconductor layer L2 may include a second substrate. A transistor and a wiring pattern for the semiconductor device may be formed on the second substrate to configure the peripheral circuitry (200 in FIG. 1).

The first semiconductor layer L1 and the second semiconductor layer L2 may be formed on a single wafer. The second semiconductor layer L2 may be formed first, and then the first semiconductor layer L1 may be built up on the second semiconductor layer L2. In such a case, the memory device 10 may be defined as having a Peri Under Cell (PUC) structure. Alternatively, the first semiconductor layer L1 and the second semiconductor layer L2 may be fabricated on separate wafers and then bonded together using bonding technology. In this case, the memory device 10 may be defined as having a Peri Over Cell (POC) structure. The memory device 10 according to the present disclosure may be provided in either a PUC structure or a POC structure. Meanwhile, although not illustrated, the memory cell array (100 in FIG. 1) and the peripheral circuitry (200 in FIG. 1) may be disposed planarly on a single substrate.

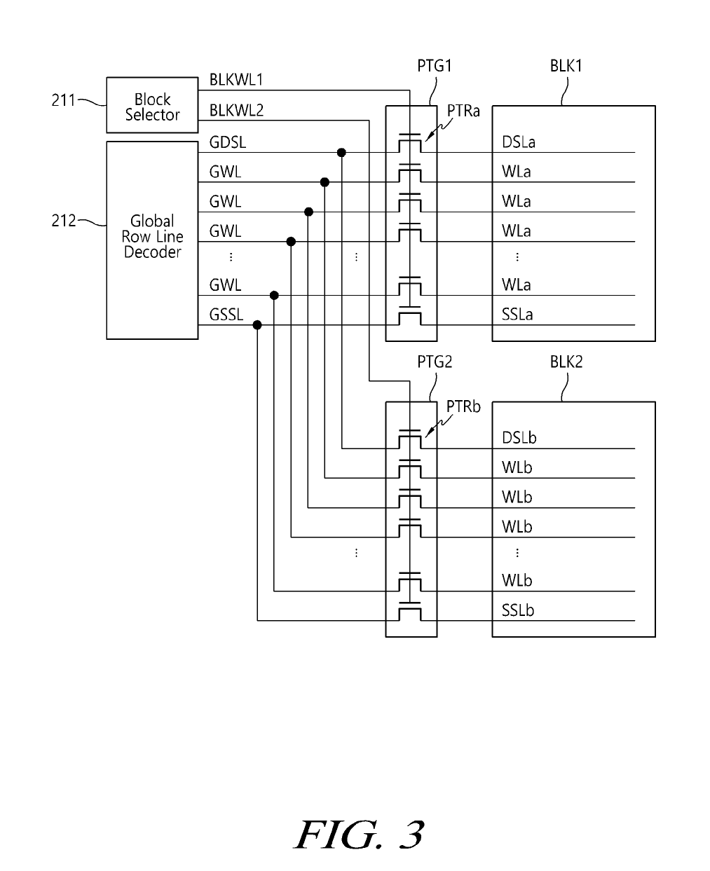

FIG. 3 illustrates first and second memory blocks, first and second pass transistor groups, a block selector, and a global row line decoder shown in FIG. 1.

Referring to FIG. 3, a first memory block BLK1 may include a plurality of first row lines DSLa, WLa, and SSLa. The first row lines DSLa, WLa, and SSLa may include a first drain select line DSLa, a plurality of first word lines WLa, and a first source select line SSLa. A second memory block BLK2 may include a plurality of second row lines DSLb, WLb, and SSLb. The second row lines DSLb, WLb, and SSLb may include a second drain select line DSLb, a plurality of second word lines WLb, and a second source select line SSLb.

The first pass transistor group PTG1 may include a plurality of pass transistors PTRa. The second pass transistor group PTG2 may include a plurality of pass transistors PTRb.

Each of the pass transistors PTRa of the first pass transistor group PTG1 may be connected between a corresponding one of the global row lines (one of GDSL, GWL, and GSSL) and a corresponding one of the first row lines (one of DSLa, WLa, and SSLa). Gate electrodes of the pass transistors PTRa of the first pass transistor group PTG1 may be commonly connected to a first block selection signal line BLKWL1, which may be connected to the block selector 211. When an activated block selection signal is provided from the block selector 211 to the first block selection signal line BLKWL1, the pass transistors PTRa of the first pass transistor group PTG1 may be turned on. Accordingly, operation voltages provided through the global row lines GDSL, GWL, and GSSL may be transferred to the first memory block BLK1 through the first row lines DSLa, WLa, and SSLa.

Each of the pass transistors PTRb of the second pass transistor group PTG2 may be connected between a corresponding one of the global row lines (one of GDSL, GWL, and GSSL) and a corresponding one of the second row lines (one of DSLb, WLb, and SSLb). Gate electrodes of the pass transistors PTRb of the second pass transistor group PTG2 may be commonly connected to a second block selection signal line BLKWL2, which may be connected to the block selector 211. When an activated block selection signal is provided from the block selector 211 to the second block selection signal line BLKWL2, the pass transistors PTRb of the second pass transistor group PTG2 may be turned on. Accordingly, operation voltages provided through the global row lines GDSL, GWL, and GSSL may be transferred to the second memory block BLK2 through the second row lines DSLb, WLb, and SSLb.

FIG. 4 is a perspective view schematically illustrating first and second memory blocks of FIG. 1.

Referring to FIG. 4, a first memory block BLK1 and a second memory block BLK2 are disposed on a first substrate SUB1. The first memory block BLK1 and the second memory block BLK2 are adjacent to each other along a second horizontal direction HD2 that intersects a first horizontal direction HD1.

The first memory block BLK1 may include a plurality of first interlayer insulating layers 11 and a plurality of first electrode layers 21 that are alternately stacked on the first substrate SUB1. The first memory block BLK1 may further include a plurality of first cell plugs 31 that vertically penetrate the plurality of first interlayer insulating layers 11 and the plurality of first electrode layers 21.

At least one of the lowermost first electrode layers 21 may form a source select line, and at least one of the uppermost first electrode layers 21 may form a drain select line. The first electrode layers 21 between the source select line and the drain select line may form word lines. The first electrode layers 21 may include a plurality of first odd electrode layers 21o and a plurality of first even electrode layers 21e alternately stacked in a vertical direction VD. The first odd electrode layers 21o are disposed at odd-numbered positions from the first substrate SUB1 among the first electrode layers 21, and the first even electrode layers 21e are disposed at even-numbered positions from the first substrate SUB1 among the first electrode layers 21.

Each of the first cell plugs 31 may include a first channel layer 31A and a first cell gate insulating layer 31B. The first channel layer 31A may include polysilicon or monocrystalline silicon, and may include a p-type impurity such as boron (B) in some regions. The first cell gate insulating layer 31B may surround an outer wall of the first channel layer 31A. The first cell gate insulating layer 31B may include a tunnel insulating film, a charge storage layer, and a blocking film that are sequentially stacked from the outer wall of the first channel layer 31A. In some embodiments, the first cell gate insulating layer 31B may have an ONO (Oxide-Nitride-Oxide) structure in which an oxide film, a nitride film, and another oxide film are sequentially stacked.

The second memory block BLK2 may include a plurality of second interlayer insulating layers 12 and a plurality of second electrode layers 22 that are alternately stacked on the first substrate SUB1. The second memory block BLK2 may further include a plurality of second cell plugs 32 that vertically penetrate the plurality of second interlayer insulating layers 12 and the plurality of second electrode layers 22.

At least one of the lowermost second electrode layers 22 may form a source select line, and at least one of the uppermost second electrode layers 22 may form a drain select line. The second electrode layers 22 between the source select line and the drain select line may form word lines. The second electrode layers 22 may include a plurality of second odd electrode layers 22o and a plurality of second even electrode layers 22e that are alternately stacked in a vertical direction VD. The second odd electrode layers 22o are disposed at odd-numbered positions from the first substrate SUB1 among the second electrode layers 22, and the second even electrode layers 22e are disposed at even-numbered positions from the first substrate SUB1 among the second electrode layers 22.

Each of the second cell plugs 32 may include a second channel layer 32A and a second cell gate insulating layer 32B. The second channel layer 32A may be made of the same material as the first channel layer 31A. The second cell gate insulating layer 32B may surround an outer wall of the second channel layer 32A, and may have a structure similar to the first cell gate insulating layer 31B.

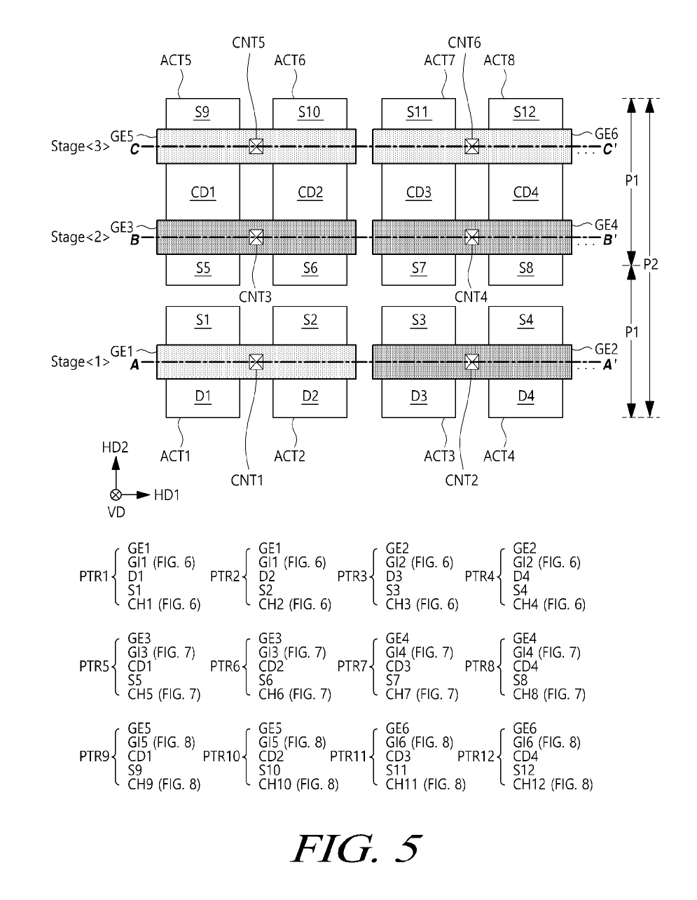

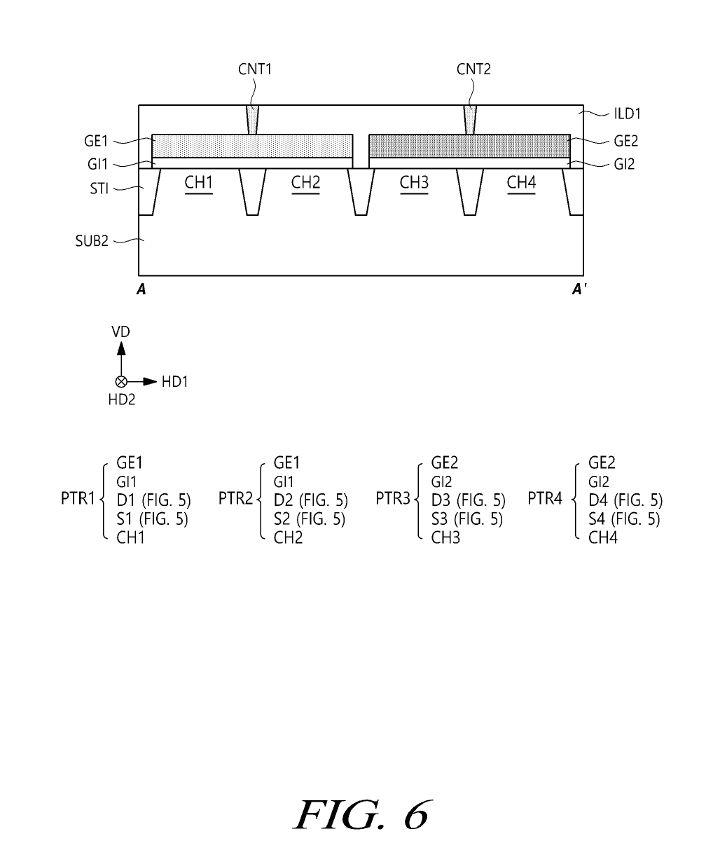

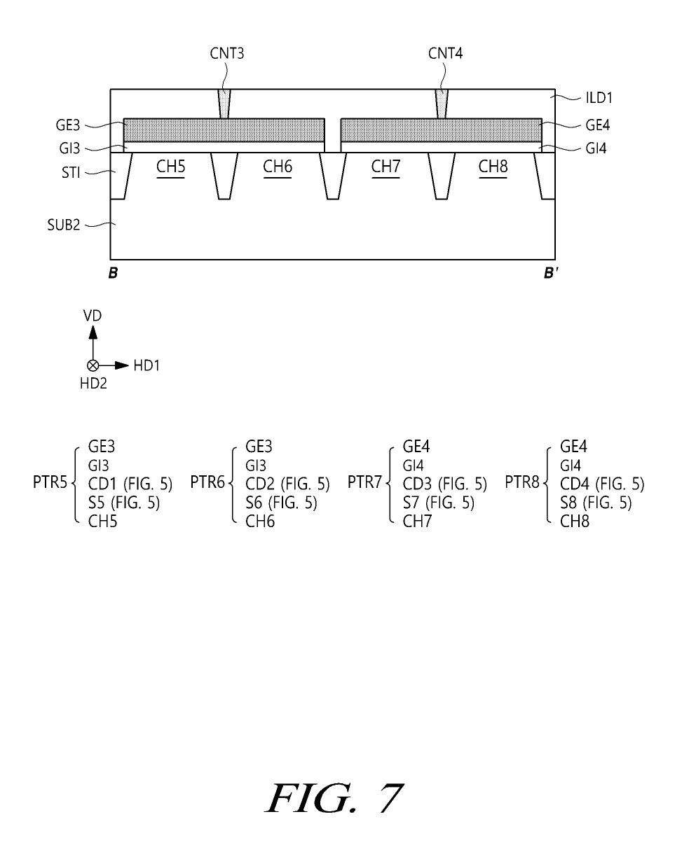

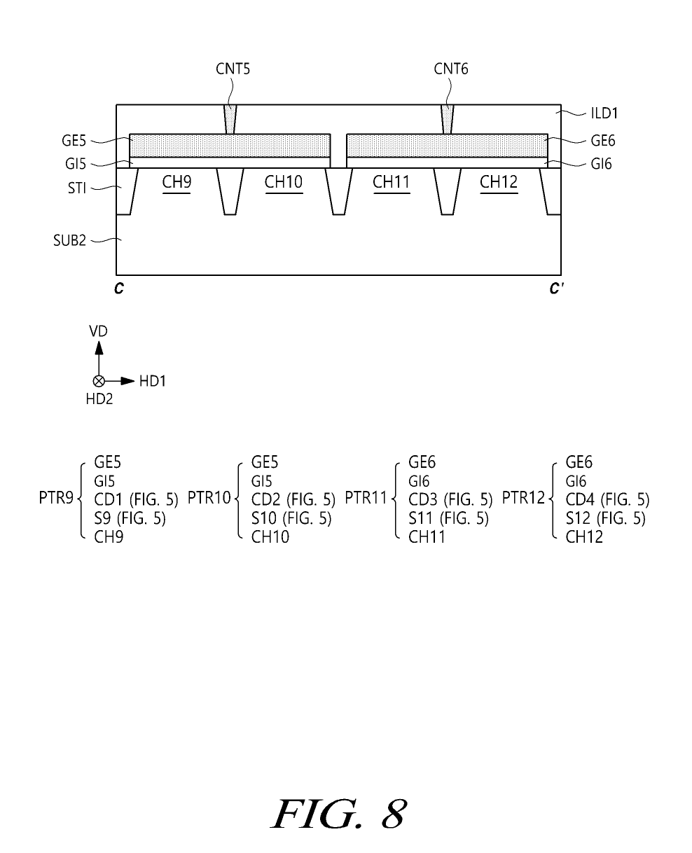

FIG. 5 is a plan view schematically illustrating a portion of a pass transistor circuit according to an embodiment of the present disclosure. FIG. 6 is a cross-sectional view taken along line A-A’ of FIG. 5. FIG. 7 is a cross-sectional view taken along line B-B’ of FIG. 5. FIG. 8 is a cross-sectional view taken along line C-C’ of FIG. 5. FIG. 5 illustrates pass transistors included in the first and second pass transistor groups PTG1 and PTG2 of FIGS. 1 and 3.

Referring to FIG. 5 through FIG. 8, a first pass transistor group PTG1 may include first, second, ninth, tenth, eleventh, and twelfth pass transistors PTR1, PTR2, PTR9, PTR10, PTR11, and PTR12. The second pass transistor group PTG2 may include third, fourth, fifth, sixth, seventh, and eighth pass transistors PTR3, PTR4, PTR5, PTR6, PTR7, and PTR8. The pass transistors PTR1 through PTR12 of the first and second pass transistor groups PTG1 and PTG2 may be arranged in three stages.

Among the pass transistors of the first pass transistor group PTG1, the first and second pass transistors PTR1 and PTR2 may be arranged in a first stage (Stage<1>), and the ninth through twelfth pass transistors PTR9, PTR10, PTR11, and PTR12 may be arranged in a third stage (Stage<3>). Among the pass transistors of the second pass transistor group PTG2, the third and fourth pass transistors PTR3 and PTR4 may be arranged in the first stage (Stage<1>), and the fifth through eighth pass transistors PTR5, PTR6, PTR7, and PTR8 may be arranged in a second stage (Stage<2>).

A dimension of the first memory block BLK1 in the second horizontal direction HD2 and a dimension of the second memory block BLK2 in the second horizontal direction HD2 may each be P1. A total of the dimensions in the second horizontal direction HD2 of the first stage (Stage<1>), the second stage (Stage<2>), and the third stage (Stage<3>) may be P2, which may be two times P1 (i.e., P1 × 2).

Device isolation layers STI may be formed on the second substrate SUB2 to define active regions and device isolation regions. The device isolation regions are regions where the STI is formed, and the active regions are regions where the STI is not formed. The STI is disposed between adjacent active regions.

The active regions may include first through eighth active regions ACT1 through ACT8. The first through fourth active regions ACT1 through ACT4 may be arranged in a row along the first horizontal direction HD1. The fifth active region ACT5 is adjacent to the first active region ACT1 in the second horizontal direction HD2. The sixth active region ACT6 is adjacent to the second active region ACT2 in the second horizontal direction HD2. The seventh active region ACT7 is adjacent to the third active region ACT3 in the second horizontal direction HD2. The eighth active region ACT8 is adjacent to the fourth active region ACT4 in the second horizontal direction HD2. The fifth through eighth active regions ACT5 through ACT8 may also be arranged in a row along the first horizontal direction HD1.

The first pass transistor PTR1 includes a first gate insulating film GI1 on the second substrate SUB2, a first gate electrode GE1 on the first gate insulating film GI1, and a first source region S1 and a first drain region D1 formed in the first active region ACT1 on both sides of the first gate electrode GE1. A first channel region CH1 of the first pass transistor PTR1 is formed in the first active region ACT1 between the first source region S1 and the first drain region D1 under the first gate electrode GE1.

The second pass transistor PTR2 is adjacent to the first pass transistor PTR1 in the first horizontal direction HD1. The second pass transistor PTR2 includes the first gate insulating film GI1 on the second substrate SUB2, the first gate electrode GE1 on the first gate insulating film GI1, and a second source region S2 and a second drain region D2 formed in the second active region ACT2 of the second substrate SUB2 on both sides of the first gate electrode GE1. A second channel region CH2 of the second pass transistor PTR2 is formed in the second active region ACT2 between the second source region S2 and the second drain region D2 under the first gate electrode GE1.

The third pass transistor PTR3 is adjacent to the second pass transistor PTR2 in the first horizontal direction HD1. The third pass transistor PTR3 includes a second gate insulating film GI2 on the second substrate SUB2, a second gate electrode GE2 on the second gate insulating film GI2, and a third source region S3 and a third drain region D3 formed in the third active region ACT3 of the second substrate SUB2 on both sides of the second gate electrode GE2. A third channel region CH3 of the third pass transistor PTR3 is formed in the third active region ACT3 between the third source region S3 and the third drain region D3 under the second gate electrode GE2.

A fourth pass transistor PTR4 is adjacent to the third pass transistor PTR3 in the first horizontal direction HD1. The fourth pass transistor PTR4 includes a second gate insulating film GI2 on the second substrate SUB2, a second gate electrode GE2 on the second gate insulating film GI2, and a fourth source region S4 and a fourth drain region D4 formed in a fourth active region ACT4 of the second substrate SUB2 on both sides of the second gate electrode GE2. A fourth channel region CH4 of the fourth pass transistor PTR4 is formed in the fourth active region ACT4 between the fourth source region S4 and the fourth drain region D4 under the second gate electrode GE2.

A fifth pass transistor PTR5 is adjacent to the first pass transistor PTR1 in the second horizontal direction HD2. The fifth pass transistor PTR5 includes a third gate insulating film GI3 on the second substrate SUB2, a third gate electrode GE3 on the third gate insulating film GI3, and a fifth source region S5 and a first common drain region CD1 formed in a fifth active region ACT5 of the second substrate SUB2 on both sides of the third gate electrode GE3. A fifth channel region CH5 of the fifth pass transistor PTR5 is formed in the fifth active region ACT5 between the fifth source region S5 and the first common drain region CD1 under the third gate electrode GE3.

A sixth pass transistor PTR6 is adjacent to the fifth pass transistor PTR5 in the first horizontal direction HD1 and adjacent to the second pass transistor PTR2 in the second horizontal direction HD2. The sixth pass transistor PTR6 includes the third gate insulating film GI3 on the second substrate SUB2, the third gate electrode GE3 on the third gate insulating film GI3, and a sixth source region S6 and a second common drain region CD2 formed in a sixth active region ACT6 of the second substrate SUB2 on both sides of the third gate electrode GE3. A sixth channel region CH6 of the sixth pass transistor PTR6 is formed in the sixth active region ACT6 between the sixth source region S6 and the second common drain region CD2 under the third gate electrode GE3.

A seventh pass transistor PTR7 is adjacent to the sixth pass transistor PTR6 in the first horizontal direction HD1 and adjacent to the third pass transistor PTR3 in the second horizontal direction HD2. The seventh pass transistor PTR7 includes a fourth gate insulating film GI4 on the second substrate SUB2, a fourth gate electrode GE4 on the fourth gate insulating film GI4, and a seventh source region S7 and a third common drain region CD3 formed in a seventh active region ACT7 of the second substrate SUB2 on both sides of the fourth gate electrode GE4. A seventh channel region CH7 of the seventh pass transistor PTR7 is formed in the seventh active region ACT7 between the seventh source region S7 and the third common drain region CD3 under the fourth gate electrode GE4.

An eighth pass transistor PTR8 is adjacent to the seventh pass transistor PTR7 in the first horizontal direction HD1 and adjacent to the fourth pass transistor PTR4 in the second horizontal direction HD2. The eighth pass transistor PTR8 includes the fourth gate insulating film GI4 on the second substrate SUB2, the fourth gate electrode GE4 on the fourth gate insulating film GI4, and an eighth source region S8 and a fourth common drain region CD4 formed in an eighth active region ACT8 of the second substrate SUB2 on both sides of the fourth gate electrode GE4. An eighth channel region CH8 of the eighth pass transistor PTR8 is formed in the eighth active region ACT8 between the eighth source region S8 and the fourth common drain region CD4 under the fourth gate electrode GE4.

A ninth pass transistor PTR9 is adjacent to the fifth pass transistor PTR5 in the second horizontal direction HD2. The ninth pass transistor PTR9 includes a fifth gate insulating film GI5 on the second substrate SUB2, a fifth gate electrode GE5 on the fifth gate insulating film GI5, and a ninth source region S9 and the first common drain region CD1 formed in the fifth active region ACT5 of the second substrate SUB2 on both sides of the fifth gate electrode GE5. The fifth pass transistor PTR5 and the ninth pass transistor PTR9 share the first common drain region CD1. A ninth channel region CH9 of the ninth pass transistor PTR9 is formed in the fifth active region ACT5 between the ninth source region S9 and the first common drain region CD1 under the fifth gate electrode GE5.

A tenth pass transistor PTR10 is adjacent to the ninth pass transistor PTR9 in the first horizontal direction HD1 and adjacent to the sixth pass transistor PTR6 in the second horizontal direction HD2. The tenth pass transistor PTR10 includes the fifth gate insulating film GI5 on the second substrate SUB2, the fifth gate electrode GE5 on the fifth gate insulating film GI5, and a tenth source region S10 and the second common drain region CD2 formed in the sixth active region ACT6 of the second substrate SUB2 on both sides of the fifth gate electrode GE5. The sixth pass transistor PTR6 and the tenth pass transistor PTR10 share the second common drain region CD2. A tenth channel region CH10 of the tenth pass transistor PTR10 is formed in the sixth active region ACT6 between the tenth source region S10 and the second common drain region CD2 under the fifth gate electrode GE5.

An eleventh pass transistor PTR11 is adjacent to the seventh pass transistor PTR7 in the second horizontal direction HD2. The eleventh pass transistor PTR11 includes a sixth gate insulating film GI6 on the second substrate SUB2, a sixth gate electrode GE6 on the sixth gate insulating film GI6, and an eleventh source region S11 and the third common drain region CD3 formed in the seventh active region ACT7 of the second substrate SUB2 on both sides of the sixth gate electrode GE6. The seventh pass transistor PTR7 and the eleventh pass transistor PTR11 share the third common drain region CD3. An eleventh channel region CH11 of the eleventh pass transistor PTR11 is formed in the seventh active region ACT7 between the eleventh source region S11 and the third common drain region CD3 under the sixth gate electrode GE6.

A twelfth pass transistor PTR12 is adjacent to the eleventh pass transistor PTR11 in the first horizontal direction HD1 and adjacent to the eighth pass transistor PTR8 in the second horizontal direction HD2. The twelfth pass transistor PTR12 includes the sixth gate insulating film GI6 on the second substrate SUB2, the sixth gate electrode GE6 on the sixth gate insulating film GI6, and a twelfth source region S12 and the fourth common drain region CD4 formed in the eighth active region ACT8 of the second substrate SUB2 on both sides of the sixth gate electrode GE6. The eighth pass transistor PTR8 and the twelfth pass transistor PTR12 share the fourth common drain region CD4. A twelfth channel region CH12 of the twelfth pass transistor PTR12 is formed in the eighth active region ACT8 between the twelfth source region S12 and the fourth common drain region CD4 under the sixth gate electrode GE6.

In each of the first, second, and third stages (Stage<1>, Stage<2>, and Stage<3>), two neighboring pass transistors in the first horizontal direction HD1 form a pair sharing a gate electrode. For example, the first and second pass transistors PTR1 and PTR2 share the first gate electrode GE1. The third and fourth pass transistors PTR3 and PTR4 share the second gate electrode GE2. The fifth and sixth pass transistors PTR5 and PTR6 share the third gate electrode GE3. The seventh and eighth pass transistors PTR7 and PTR8 share the fourth gate electrode GE4. The ninth and tenth pass transistors PTR9 and PTR10 share the fifth gate electrode GE5. The eleventh and twelfth pass transistors PTR11 and PTR12 share the sixth gate electrode GE6.

A first insulating layer ILD1 may be disposed on the second substrate SUB2 to cover the first through twelfth pass transistors PTR1 through PTR12.

As shown in FIG. 5 and FIG. 6, a first contact CNT1 may be disposed on the first gate electrode GE1. The first contact CNT1 may penetrate the first insulating layer ILD1 in a vertical direction VD to connect to the first gate electrode GE1. The first contact CNT1 may be disposed over a device isolation region between the first and second pass transistors PTR1 and PTR2. The first contact CNT1 may vertically overlap a device isolation layer STI between the first and second pass transistors PTR1 and PTR2. The first contact CNT1 may be non-overlapping with the first channel region CH1 of the first pass transistor PTR1 and the second channel region CH2 of the second pass transistor PTR2.

As shown in FIG. 5 and FIG. 6, a second contact CNT2 may be disposed on the second gate electrode GE2. The second contact CNT2 may penetrate the first insulating layer ILD1 in the vertical direction VD to connect to the second gate electrode GE2. The second contact CNT2 may be disposed over a device isolation region between the third and fourth pass transistors PTR3 and PTR4. The second contact CNT2 may vertically overlap a device isolation layer STI between the third and fourth pass transistors PTR3 and PTR4. The second contact CNT2 may be non-overlapping with the third channel region CH3 of the third pass transistor PTR3 and the fourth channel region CH4 of the fourth pass transistor PTR4.

As shown in FIG. 5 and FIG. 7, a third contact CNT3 may be disposed on the third gate electrode GE3. The third contact CNT3 may penetrate the first insulating layer ILD1 in the vertical direction VD to connect to the third gate electrode GE3. The third contact CNT3 may be disposed over a device isolation region between the fifth and sixth pass transistors PTR5 and PTR6. The third contact CNT3 may vertically overlap a device isolation layer STI between the fifth and sixth pass transistors PTR5 and PTR6. The third contact CNT3 may be non-overlapping with the fifth channel region CH5 of the fifth pass transistor PTR5 and the sixth channel region CH6 of the sixth pass transistor PTR6.

As shown in FIG. 5 and FIG. 7, a fourth contact CNT4 may be disposed on the fourth gate electrode GE4. The fourth contact CNT4 may penetrate the first insulating layer ILD1 in the vertical direction VD to connect to the fourth gate electrode GE4. The fourth contact CNT4 may be disposed over a device isolation region between the seventh and eighth pass transistors PTR7 and PTR8. The fourth contact CNT4 may vertically overlap a device isolation layer STI between the seventh and eighth pass transistors PTR7 and PTR8. The fourth contact CNT4 may be non-overlapping with the seventh channel region CH7 of the seventh pass transistor PTR7 and the eighth channel region CH8 of the eighth pass transistor PTR8.

As shown in FIG. 5 and FIG. 8, a fifth contact CNT5 may be disposed on the fifth gate electrode GE5. The fifth contact CNT5 may penetrate the first insulating layer ILD1 in the vertical direction VD to connect to the fifth gate electrode GE5. The fifth contact CNT5 may be disposed over a device isolation region between the ninth and tenth pass transistors PTR9 and PTR10. The fifth contact CNT5 may vertically overlap a device isolation layer STI between the ninth and tenth pass transistors PTR9 and PTR10. The fifth contact CNT5 may be non-overlapping with the ninth channel region CH9 of the ninth pass transistor PTR9 and the tenth channel region CH10 of the tenth pass transistor PTR10.

As shown in FIG. 5 and FIG. 8, a sixth contact CNT6 may be disposed on the sixth gate electrode GE6. The sixth contact CNT6 may penetrate the first insulating layer ILD1 in the vertical direction VD to connect to the sixth gate electrode GE6. The sixth contact CNT6 may be disposed over a device isolation region between the eleventh and twelfth pass transistors PTR11 and PTR12. The sixth contact CNT6 may vertically overlap a device isolation layer STI between the eleventh and twelfth pass transistors PTR11 and PTR12. The sixth contact CNT6 may be non-overlapping with the eleventh channel region CH11 of the eleventh pass transistor PTR11 and the twelfth channel region CH12 of the twelfth pass transistor PTR12.

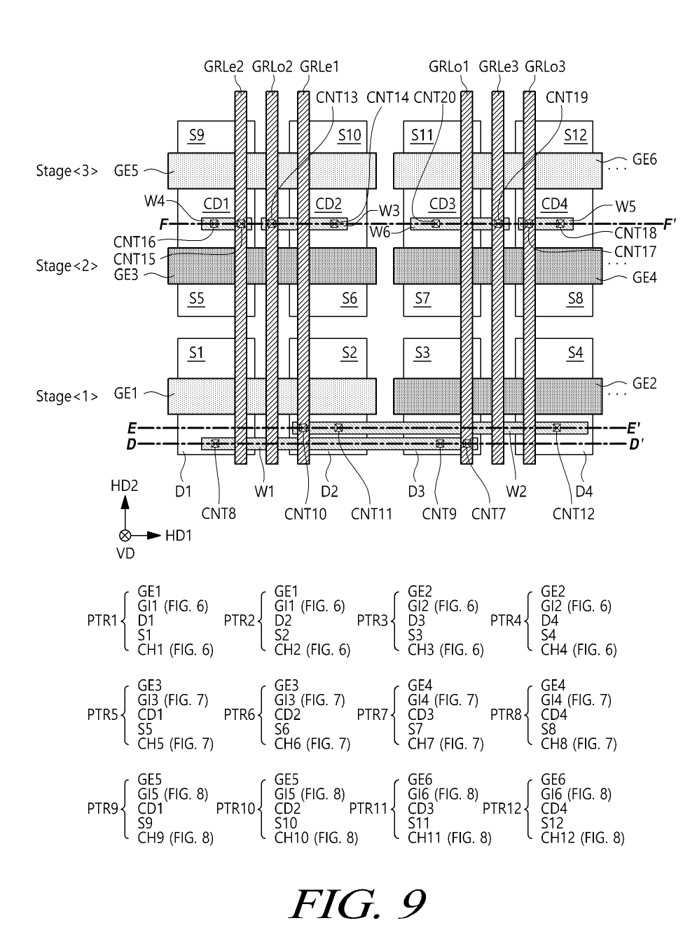

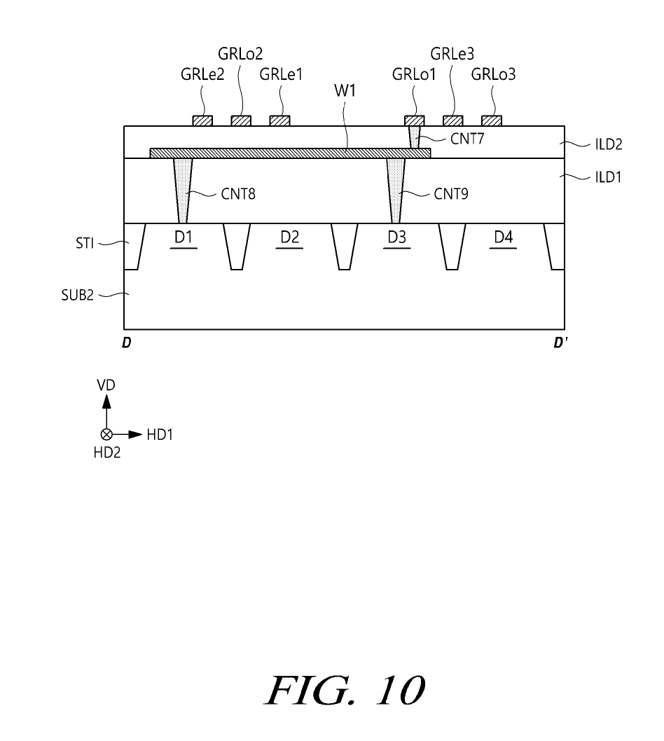

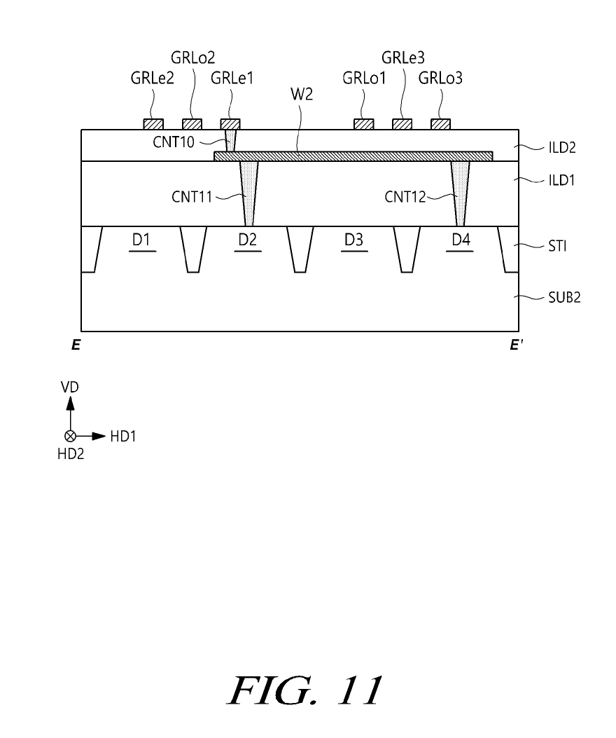

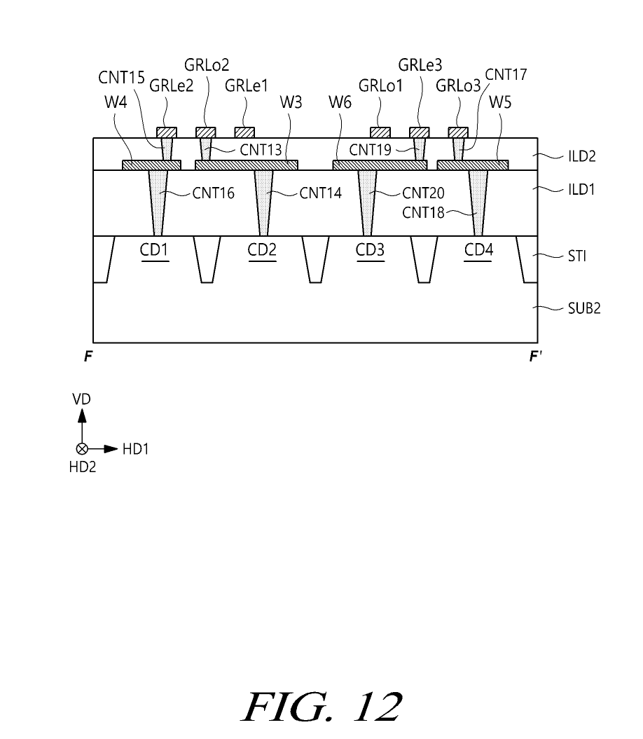

FIG. 9 is a plan view illustrating pass transistors and global row lines according to an embodiment of the present disclosure. FIG. 10 is a cross-sectional view taken along line D-D’ of FIG. 9. FIG. 11 is a cross-sectional view taken along line E-E’ of FIG. 9. FIG. 12 is a cross-sectional view taken along line F-F’ of FIG. 9.

Referring to FIG. 9 through FIG. 12, first through sixth wirings W1 to W6 may be disposed on the first insulating layer ILD1. A second insulating layer ILD2 may be disposed on the first insulating layer ILD1 to cover the wirings W1 to W6. Global row lines GRLo1 to GRLo3 and GRLe1 to GRLe3 may be disposed on the second insulating layer ILD2. The global row lines may include a plurality of odd global row lines GRLo1 to GRLo3 and a plurality of even global row lines GRLe1 to GRLe3, which are alternately arranged along the first horizontal direction HD1.

The odd global row lines GRLo1 to GRLo3 include a first odd global row line GRLo1, a second odd global row line GRLo2, and a third odd global row line GRLo3. The even global row lines GRLe1 to GRLe3 include a first even global row line GRLe1, a second even global row line GRLe2, and a third even global row line GRLe3.

As shown in FIG. 9 and FIG. 10, a first odd global row line GRLo1 may be commonly connected to the first and third pass transistors PTR1 and PTR3. The first odd global row line GRLo1 may be connected to a first wiring W1 through a seventh contact CNT7 penetrating a second insulating layer ILD2 in a vertical direction VD. The first wiring W1 may be connected to the drain region D1 of the first pass transistor PTR1 through an eighth contact CNT8 penetrating a first insulating layer ILD1 in the vertical direction VD. The first wiring W1 may also be connected to the drain region D3 of the third pass transistor PTR3 through a ninth contact CNT9 penetrating the first insulating layer ILD1 in the vertical direction VD. Accordingly, the first odd global row line GRLo1 may be connected to the first drain region D1 via the seventh contact CNT7, the first wiring W1, and the eighth contact CNT8, and to the third drain region D3 via the seventh contact CNT7, the first wiring W1, and the ninth contact CNT9.

As shown in FIG. 9 and FIG. 11, a first even global row line GRLe1 may be commonly connected to the second and fourth pass transistors PTR2 and PTR4. The first even global row line GRLe1 may be connected to a second wiring W2 through a tenth contact CNT10 penetrating the second insulating layer ILD2 in the vertical direction VD. The second wiring W2 may be connected to the second drain region D2 of the second pass transistor PTR2 through an eleventh contact CNT11 penetrating the first insulating layer ILD1 in the vertical direction VD, and to the fourth drain region D4 of the fourth pass transistor PTR4 through a twelfth contact CNT12 penetrating the first insulating layer ILD1 in the vertical direction VD. Accordingly, the first even global row line GRLe1 may be connected to the second drain region D2 via the tenth contact CNT10, the second wiring W2, and the eleventh contact CNT11, and to the fourth drain region D4 via the tenth contact CNT10, the second wiring W2, and the twelfth contact CNT12.

As shown in FIG. 9 and FIG. 12, a second odd global row line GRLo2 may be commonly connected to the sixth and tenth pass transistors PTR6 and PTR10. The second odd global row line GRLo2 may be connected to a third wiring W3 through a thirteenth contact CNT13 penetrating the second insulating layer ILD2 in the vertical direction VD. The third wiring W3 may be connected to the second common drain region CD2 through a fourteenth contact CNT14 penetrating the first insulating layer ILD1 in the vertical direction VD. Accordingly, the second odd global row line GRLo2 may be connected to the second common drain region CD2 via the thirteenth contact CNT13, the third wiring W3, and the fourteenth contact CNT14.

As shown in FIG. 9 and FIG. 12, a second even global row line GRLe2 may be commonly connected to the fifth and ninth pass transistors PTR5 and PTR9. The second even global row line GRLe2 may be connected to a fourth wiring W4 through a fifteenth contact CNT15 penetrating the second insulating layer ILD2 in the vertical direction VD. The fourth wiring W4 may be connected to the first common drain region CD1 through a sixteenth contact CNT16 penetrating the first insulating layer ILD1 in the vertical direction VD. Accordingly, the second even global row line GRLe2 may be connected to the first common drain region CD1 via the fifteenth contact CNT15, the fourth wiring W4, and the sixteenth contact CNT16.

As shown in FIG. 9 and FIG. 12, a third odd global row line GRLo3 may be commonly connected to the eighth and twelfth pass transistors PTR8 and PTR12. The third odd global row line GRLo3 may be connected to a fifth wiring W5 through a seventeenth contact CNT17 penetrating the second insulating layer ILD2 in the vertical direction VD. The fifth wiring W5 may be connected to the fourth common drain region CD4 through an eighteenth contact CNT18 penetrating the first insulating layer ILD1 in the vertical direction VD. Accordingly, the third odd global row line GRLo3 may be connected to the fourth common drain region CD4 via the seventeenth contact CNT17, the fifth wiring W5, and the eighteenth contact CNT18.

As shown in FIG. 9 and FIG. 12, a third even global row line GRLe3 may be commonly connected to the seventh and eleventh pass transistors PTR7 and PTR11. The third even global row line GRLe3 may be connected to a sixth wiring W6 through a nineteenth contact CNT19 penetrating the second insulating layer ILD2 in the vertical direction VD. The sixth wiring W6 may be connected to the third common drain region CD3 through a twentieth contact CNT20 penetrating the first insulating layer ILD1 in the vertical direction VD. Accordingly, the third even global row line GRLe3 may be connected to the third common drain region CD3 via the nineteenth contact CNT19, the sixth wiring W6, and the twentieth contact CNT20.

Referring to FIG. 4 and FIG. 9 together, each of a first source region S1 of the first pass transistor PTR1, a tenth source region S10 of the tenth pass transistor PTR10, and a twelfth source region S12 of the twelfth pass transistor PTR12 may be connected to a corresponding one of the first odd electrode layers 21o of the first memory block BLK1. Each of a second source region S2 of the second pass transistor PTR2, a ninth source region S9 of the ninth pass transistor PTR9, and an eleventh source region S11 of the eleventh pass transistor PTR11 may be connected to a corresponding one of the first even electrode layers 21e of the first memory block BLK1.

Each of a third source region S3 of the third pass transistor PTR3, a sixth source region S6 of the sixth pass transistor PTR6, and an eighth source region S8 of the eighth pass transistor PTR8 may be connected to a corresponding one of the second odd electrode layers 22o of the second memory block BLK2. Each of a fourth source region S4 of the fourth pass transistor PTR4, a fifth source region S5 of the fifth pass transistor PTR5, and a seventh source region S7 of the seventh pass transistor PTR7 may be connected to a corresponding one of the second even electrode layers 22e of the second memory block BLK2.

The first through fourth pass transistors PTR1, PTR2, PTR3, and PTR4, which are sequentially arranged in the first stage Stage<1>, may each be connected to one of the first odd electrode layers 21o, the first even electrode layers 21e, the second odd electrode layers 22o, and the second even electrode layers 22e, respectively.

The first odd electrode layer 21o connected to the first pass transistor PTR1 may be disposed at a K-th position (where K is an odd number) from the second substrate SUB2 among the first electrode layers 21. The second odd electrode layer 22o connected to the third pass transistor PTR3 may be disposed at the K-th position from the second substrate SUB2 among the second electrode layers 22. The first odd electrode layer 21o connected to the first pass transistor PTR1 and the second odd electrode layer 22o connected to the third pass transistor PTR3 may be disposed at the same height level from the second substrate SUB2.

The first even electrode layer 21e connected to the second pass transistor PTR2 may be disposed at an M-th position (where M is an even number) from the second substrate SUB2 among the first electrode layers 21. The second even electrode layer 22e connected to the fourth pass transistor PTR4 may be disposed at the M-th position from the second substrate SUB2 among the second electrode layers 22. The first even electrode layer 21e and the second even electrode layer 22e may also be disposed at the same height level from the second substrate SUB2.

M may be equal to K+1. The first odd electrode layer 21o connected to the first pass transistor PTR1 and the first even electrode layer 21e connected to the second pass transistor PTR2 among the first electrode layers 21 may be adjacent to each other. Likewise, the second odd electrode layer 22o connected to the third pass transistor PTR3 and the second even electrode layer 22e connected to the fourth pass transistor PTR4 among the second electrode layers 22 may also be adjacent to each other.

In the second mode, a first test voltage and a second test voltage may be alternately applied to the first, second, and third odd global row lines GRLo1, GRLo2, and GRLo3. In the second mode, the first test voltage and the second test voltage may also be alternately applied to the first, second, and third even global row lines GRLe1, GRLe2, and GRLe3. At the same point in time, the test voltages applied to the first, second, and third odd global row lines GRLo1, GRLo2, and GRLo3 may be different from the test voltages applied to the first, second, and third even global row lines GRLe1, GRLe2, and GRLe3. For example, while the first test voltage is applied to the odd global row lines GRLo1, GRLo2, and GRLo3, the second test voltage may be applied to the even global row lines GRLe1, GRLe2, and GRLe3, and while the second test voltage is applied to the odd global row lines GRLo1, GRLo2, and GRLo3, the first test voltage may be applied to the even global row lines GRLe1, GRLe2, and GRLe3.

According to an embodiment of the present disclosure, because the odd and even global row lines are alternately arranged, stress may be applied to the global row lines in the second mode. When such stress is applied, a short circuit may occur between adjacent global row lines at a weak point. After artificial stress is applied in the second mode, a defect in the global row lines may be detected through a test.

Although FIG. 5 through FIG. 12 illustrate only twelve pass transistors connected to the first and second memory blocks (BLK1, BLK2 of FIG. 1), the disclosure is not limited thereto. A plurality of such units, each comprising twelve pass transistors, may be arranged along the first horizontal direction HD1. While FIG. 5 and FIG. 12 show that the pass transistors connected to the first and second memory blocks BLK1 and BLK2 in FIG. 1 are arranged in three stages, the pass transistors connected to memory blocks BLK1 through BLKn in the memory cell array 100 of FIG. 1 may be arranged in a plurality of stages along the second horizontal direction HD2.

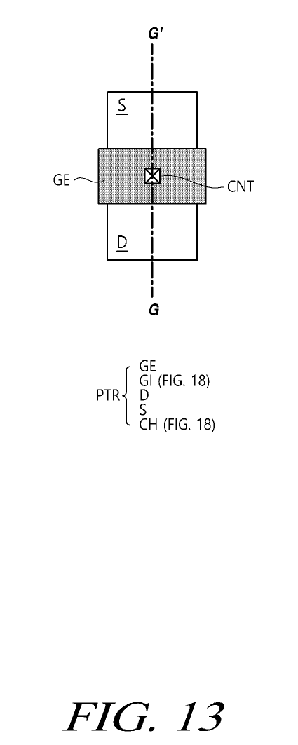

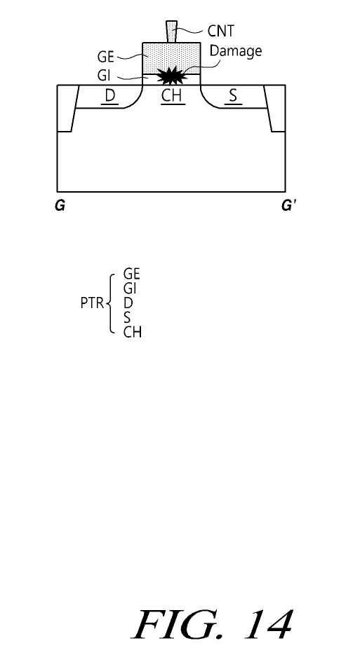

FIG. 13 is a plan view showing a pass transistor according to a comparative example, and FIG. 14 is a cross-sectional view taken along line G-G’ of FIG. 13.

Referring to FIG. 13 and FIG. 14, a contact CNT may be connected to a gate electrode GE of a pass transistor PTR. The contact CNT may be disposed on the channel region CH of the pass transistor PTR. When the contact CNT is disposed on the channel region CH, the gate insulating layer GI above the channel region CH may be damaged by the voltage applied to the contact CNT, resulting in a reduction in thickness of the gate insulating layer GI. Consequently, gate leakage current or hot carrier injection may occur.

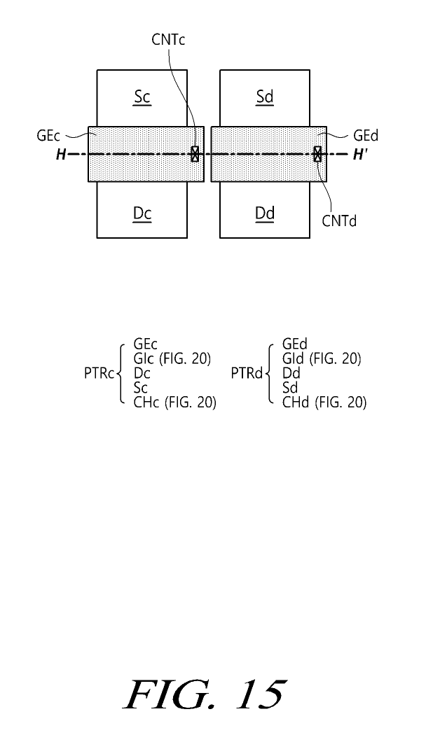

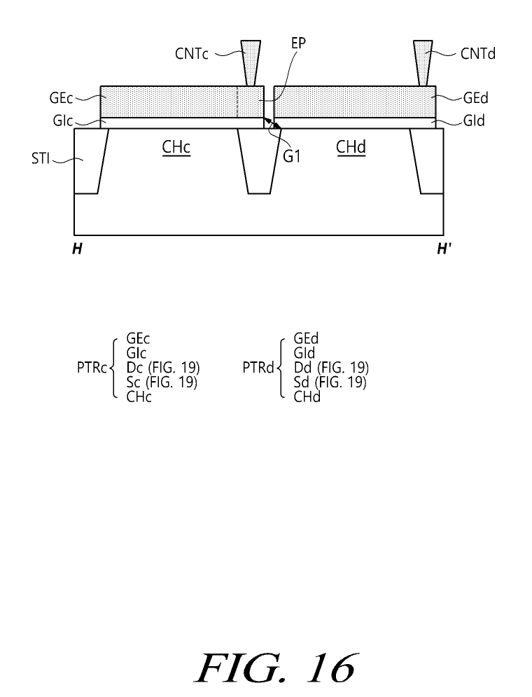

FIG. 15 is a plan view illustrating a pass transistor according to another comparative example, and FIG. 16 is a cross-sectional view taken along line H-H’ of FIG. 15.

Referring to FIG. 15 and FIG. 16, a left-side pass transistor PTRc includes a gate insulating film GIc, a gate electrode GEc, a source region Sc, a drain region Dc, and a channel region CHc. A right-side pass transistor PTRd includes a gate insulating film GId, a gate electrode GEd, a source region Sd, a drain region Dd, and a channel region CHd.

A contact CNTc is connected to the gate electrode GEc, and another contact CNTc is connected to the gate electrode GEd. Each of the gate electrodes GEc and GEd may extend over a device isolation layer STI. As shown in FIG. 16, the gate electrode GEc of the left-side pass transistor PTRc may include an extension portion EP vertically overlapping the device isolation layer STI. The contact CNTc may be disposed on the extension portion EP of the gate electrode GEc, and thus, it may be placed over the device isolation layer STI. Since the contact CNTc is not placed over the channel region CHc, damage to the gate insulating film GIc over the channel region CHc may be suppressed. However, the gap G1 between the contact CNTc and the channel region CHd of the right-side pass transistor PTRd may become narrow, potentially causing a parasitic channel to be formed in the right-side pass transistor PTRd due to the voltage applied to the contact CNTc.

According to an embodiment of the present disclosure, by configuring the pass transistors in pairs such that each pair shares a single gate electrode and disposing a contact on a device isolation layer between the two paired pass transistors, it is possible to prevent damage to the gate insulating layer over the channel region caused by a voltage applied to the contact, and simultaneously prevent the formation of a parasitic channel in a neighboring transistor due to the applied voltage.

The substrate on which the pass transistors are disposed may include silicon (Si), which has Si dangling bonds. The dangling bonds in the substrate may degrade the hump characteristics of the pass transistors and may cause threshold voltage variation, increased leakage current, and degradation in reliability.

A technique is known in which hydrogen atoms are bonded to the dangling bonds through a hydrogen passivation process to stabilize the defect states. However, the hydrogen bonded to the dangling bonds tends to undergo out-diffusion during the fabrication process of the memory device. The amount of hydrogen out-diffusion may differ between regions overlapping with the gate electrode and regions not overlapping with the gate electrode. The amount of hydrogen out-diffusion may be greater in the regions not overlapping with the gate electrode than in the overlapping regions. If the structures of the gate electrodes of the pass transistors differ from each other, there may be a difference in hydrogen out-diffusion between the pass transistors, resulting in variations in their hump characteristics. When the variation in hump characteristics is large, a tuning process intended to improve the hump characteristics may successfully enhance those of one pass transistor, while degrading those of another, thereby making the tuning process difficult.

According to an embodiment of the present disclosure, the pass transistors are configured in pairs such that each pair shares a gate electrode, and the gate electrodes have substantially the same structure. As a result, differences in the amount of hydrogen out-diffusion among the pass transistors may be reduced, and variation in hump characteristics may be minimized. Accordingly, the tuning process for improving hump characteristics may become easier.

The above description merely provides an illustrative explanation of the present disclosure. Accordingly, a person of ordinary skill in the art to which the present disclosure pertains can make various modifications and variations without departing from the essential characteristics of the present disclosure. In addition, the embodiments disclosed in the present disclosure are not intended to limit the scope of the present disclosure but rather to explain it. Therefore the scope of the present disclosure should not be limited by the embodiments.

What is claimed is:

1. A memory device comprising:
a memory cell array including a plurality of row lines extending in a first horizontal direction;
a plurality of pass transistors connected to the plurality of row lines; and
a plurality of contacts connected to gate electrodes of the plurality of pass transistors,
wherein the plurality of pass transistors is arranged in a plurality of stages arranged in a second horizontal direction perpendicular to the first horizontal direction,
wherein each stage includes a pair of two pass transistors sharing a gate electrode, and
wherein a contact connected to the shared gate electrode is disposed in a vertical direction over a device isolation layer between the two paired pass transistors.

2. The memory device according to claim 1,
wherein the contact does not overlap in the vertical direction with channel regions of the two paired pass transistors.

3. The memory device according to claim 1,
wherein the memory cell array comprises a first memory block and a second memory block adjacent to each other in the second horizontal direction, and
wherein the pass transistors connected to the row lines of the first and second memory blocks are arranged in three stages.

4. The memory device according to claim 3,
wherein the pass transistors connected to the row lines of the first memory block are arranged in a first stage and a third stage,
wherein the pass transistors connected to the row lines of the second memory block are arranged in the first stage and a second stage, and
wherein the first and third stages each are disposed on opposite sides of the second stage in the second horizontal direction.

5. The memory device according to claim 4,
wherein the pass transistors in the first stage comprise:
a first pass transistor;
a second pass transistor adjacent to the first pass transistor in the first horizontal direction and sharing a first gate electrode with the first pass transistor;
a third pass transistor adjacent to the second pass transistor in the first horizontal direction; and
a fourth pass transistor adjacent to the third pass transistor in the first horizontal direction and sharing a second gate electrode with the third pass transistor,
wherein each of the first and second pass transistors is connected to a corresponding one of the row lines of the first memory block, and
wherein each of the third and fourth pass transistors is connected to a corresponding one of the row lines of the second memory block.

6. A memory device comprising:
a plurality of memory blocks arranged along a second horizontal direction perpendicular to a first horizontal direction, each including a plurality of electrode layers and a plurality of interlayer insulating layers alternately stacked in a vertical direction;
a plurality of pass transistors connected to respective ones of the plurality of electrode layers; and
a plurality of global row lines disposed on the plurality of pass transistors and connected to the electrode layers of the plurality of memory blocks through the plurality of pass transistors,
wherein the plurality of electrode layers in each of the plurality of memory blocks include a plurality of odd electrode layers and a plurality of even electrode layers alternately stacked,
wherein the plurality of global row lines includes a plurality of odd global row lines and a plurality of even global row lines alternately arranged along the second horizontal direction,
wherein each of the plurality of odd electrode layers of the plurality of memory blocks is connected to one of the plurality of odd global row lines, and
wherein each of the plurality of even electrode layers of the plurality of memory blocks is connected to one of the plurality of even global row lines.

7. The memory device according to claim 6,
wherein the plurality of memory blocks comprises a first memory block and a second memory block adjacent to each other in the second horizontal direction, and
wherein the pass transistors connected to the electrode layers of the first and second memory blocks are arranged in three stages.

8. The memory device according to claim 7,
wherein the pass transistors in a first stage among the three stages comprise:
a first pass transistor;
a second pass transistor adjacent to the first pass transistor in the first horizontal direction;
a third pass transistor adjacent to the second pass transistor in the first horizontal direction; and
a fourth pass transistor adjacent to the third pass transistor in the first horizontal direction,
wherein the first pass transistor is connected to one of the odd electrode layers of the first memory block,
wherein the second pass transistor is connected to one of the even electrode layers of the first memory block,
wherein the third pass transistor is connected to one of the odd electrode layers of the second memory block, and
wherein the fourth pass transistor is connected to one of the even electrode layers of the second memory block.

9. The memory device according to claim 8,
wherein the first and second pass transistors share a first gate electrode, and
wherein the third and fourth pass transistors share a second gate electrode.

10. The memory device according to claim 8,
wherein an electrode layer connected to the first pass transistor is disposed at a K-th position from a bottom among the electrode layers of the first memory block, where K is an odd number and equals 1 at the lowest layer in the vertical direction,
wherein an electrode layer connected to the second pass transistor is disposed at an M-th position from the bottom among the electrode layers of the first memory block, where M is an even number,
wherein an electrode layer connected to the third pass transistor is disposed at the K-th position from the bottom among the electrode layers of the second memory block, and
wherein an electrode layer connected to the fourth pass transistor is disposed at the M-th position from the bottom among the electrode layers of the second memory block.

11. The memory device according to claim 10,
wherein M is greater than K by one.

12. The memory device according to claim 8,
wherein the pass transistors in a second stage adjacent to the first stage among the three stages comprise:
a fifth pass transistor adjacent to the first pass transistor in the second horizontal direction;
a sixth pass transistor adjacent to the second pass transistor in the second horizontal direction;
a seventh pass transistor adjacent to the third pass transistor in the second horizontal direction; and
an eighth pass transistor adjacent to the fourth pass transistor in the second horizontal direction,
wherein each of the fifth and seventh pass transistors is connected to a corresponding one of the even electrode layers of the second memory block, and
wherein each of the sixth and eighth pass transistors is connected to a corresponding one of the odd electrode layers of the second memory block.

13. The memory device according to claim 12,
wherein the fifth and sixth pass transistors share a first gate electrode, and
wherein the seventh and eighth pass transistors share a second gate electrode.

14. The memory device according to claim 12,
wherein the pass transistors in a third stage adjacent to the second stage among the three stages comprise:
a ninth pass transistor sharing a first common drain region with the fifth pass transistor;
a tenth pass transistor sharing a second common drain region with the sixth pass transistor;
an eleventh pass transistor sharing a third common drain region with the seventh pass transistor; and
a twelfth pass transistor sharing a fourth common drain region with the eighth pass transistor,
wherein each of source regions of the ninth and eleventh pass transistors is connected to a corresponding one of the even electrode layers of the first memory block, and
wherein each of source regions of the tenth and twelfth pass transistors is connected to a corresponding one of the odd electrode layers of the first memory block.

15. The memory device according to claim 14,
wherein the ninth and tenth pass transistors share a first gate electrode, and
wherein the eleventh and twelfth pass transistors share a second gate electrode.

16. The memory device according to claim 14,
wherein the plurality of even global row lines comprises:
a first even global row line connected to the first common drain region;
a second even global row line commonly connected to the drain regions of the second and fourth pass transistors; and
a third even global row line connected to the third common drain region, and
wherein the plurality of odd global row lines comprises:
a first odd global row line connected to the second common drain region;
a second odd global row line commonly connected to the drain regions of the first and third pass transistors; and
a third odd global row line connected to the fourth common drain region.

17. A memory device comprising:
a first semiconductor layer; and
a second semiconductor layer overlapping the first semiconductor layer in a vertical direction,
wherein the first semiconductor layer comprises:
a first substrate; and
a plurality of memory blocks arranged along a second horizontal direction perpendicular to a first horizontal direction on the first substrate, each including a plurality of electrode layers and a plurality of interlayer insulating layers alternately stacked in the vertical direction,
wherein the second semiconductor layer comprises:
a second substrate;
a plurality of pass transistors disposed on the second substrate and connected to the electrode layers of the plurality of memory blocks; and
a plurality of contacts connected to gate electrodes of the plurality of pass transistors,
wherein the plurality of pass transistors is arranged in a plurality of stages arranged in the second horizontal direction,
each stage comprises two pass transistors paired to share a gate electrode, and
a contact connected to a single gate electrode is disposed in the vertical direction over a device isolation region of the second substrate between the two paired pass transistors.

18. The memory device according to claim 17,
wherein the contact does not overlap in the vertical direction with channel regions of the two paired pass transistors.

19. The memory device according to claim 17,
wherein the second semiconductor layer further comprises a plurality of global row lines connected to the electrode layers of the plurality of memory blocks through the plurality of pass transistors,
wherein the plurality of electrode layers in each of the plurality of memory blocks include a plurality of odd electrode layers and a plurality of even electrode layers alternately stacked,
wherein the plurality of global row lines include a plurality of odd global row lines and a plurality of even global row lines alternately arranged along the first horizontal direction,
wherein each of the odd electrode layers of the plurality of memory blocks is connected to one of the plurality of odd global row lines, and
wherein each of the even electrode layers of the plurality of memory blocks is connected to one of the plurality of even global row lines.

20. The memory device according to claim 17,
wherein the plurality of memory blocks includes a first memory block and a second memory block adjacent to each other in the second horizontal direction, and
wherein the pass transistors connected to the electrode layers of the first and second memory blocks are arranged in three stages.

21. The memory device according to claim 20,
wherein the pass transistors connected to the electrode layers of the first memory block are arranged in a first stage and a third stage, and
wherein the pass transistors connected to the electrode layers of the second memory block are arranged in the first stage and a second stage.

22. The memory device according to claim 21,
wherein the pass transistors in the first stage comprise:
a first pass transistor;
a second pass transistor adjacent to the first pass transistor in the first horizontal direction and sharing a first gate electrode with the first pass transistor;
a third pass transistor adjacent to the second pass transistor in the first horizontal direction; and
a fourth pass transistor adjacent to the third pass transistor in the first horizontal direction and sharing a second gate electrode with the third pass transistor,
wherein each of the first and second pass transistors is connected to a corresponding one of the electrode layers of the first memory block, and
wherein each of the third and fourth pass transistors is connected to a corresponding one of the electrode layers of the second memory block.

23. The memory device according to claim 22,
wherein the electrode layers of the first memory block include a plurality of first odd electrode layers and a plurality of first even electrode layers alternately stacked,
wherein the electrode layers of the second memory block include a plurality of second odd electrode layers and a plurality of second even electrode layers alternately stacked,
wherein the first pass transistor is connected to one of the plurality of first odd electrode layers,
wherein the second pass transistor is connected to one of the plurality of first even electrode layers,
wherein the third pass transistor is connected to one of the plurality of second odd electrode layers, and
wherein the fourth pass transistor is connected to one of the plurality of second even electrode layers.

24. The memory device according to claim 23,
wherein the pass transistors disposed in the second stage comprise:
a fifth pass transistor adjacent to the first pass transistor in the second horizontal direction;
a sixth pass transistor adjacent to the second pass transistor in the second horizontal direction;
a seventh pass transistor adjacent to the third pass transistor in the second horizontal direction; and
an eighth pass transistor adjacent to the fourth pass transistor in the second horizontal direction,
wherein each of the fifth and seventh pass transistors is connected to one of the second even electrode layers, and
wherein each of the sixth and eighth pass transistors is connected to one of the second odd electrode layers.

25. The memory device according to claim 24,
wherein the fifth and sixth pass transistors share the first gate electrode, and
wherein the seventh and eighth pass transistors share the second gate electrode.

26. The memory device according to claim 24,
wherein the pass transistors in the third stage adjacent to the second stage comprise:
a ninth pass transistor sharing a first common drain region with the fifth pass transistor;
a tenth pass transistor sharing a second common drain region with the sixth pass transistor;
an eleventh pass transistor sharing a third common drain region with the seventh pass transistor; and
a twelfth pass transistor sharing a fourth common drain region with the eighth pass transistor,
wherein each of source regions of the ninth and eleventh pass transistors is connected to a corresponding one of the plurality of first even electrode layers, and
wherein each of source regions of the tenth and twelfth pass transistors is connected to a corresponding one of the plurality of first odd electrode layers.

27. The memory device according to claim 26,
wherein the ninth and tenth pass transistors share a third gate electrode, and
wherein the eleventh and twelfth pass transistors share a fourth gate electrode.
